(19) United States
(12) Patent Application Publication
(10) Pub. No.: US 2026/0265584 A1
(43) Pub. Date: Sep. 10, 2026

(54) ADHESIVE COMPOSITION, FILM-LIKE ADHESIVE AND SEMICONDUCTOR PACKAGE USING SAME, AND METHOD FOR MANUFACTURING SEMICONDUCTOR PACKAGE

(71) Applicant: FURKUAWA ELECTRIC CO., LTD., Tokyo (JP)

(72) Inventors: Minoru Morita, Tokyo (JP); Kunihiko Ishiguro, Tokyo (JP)

(21) Appl. No.: 19/660,706

(22) Filed: Apr. 28, 2026

Related U.S. Application Data
(63) Continuation of application No. PCT/JP2024/038414, filed on Oct. 28, 2024.

(30) Foreign Application Priority Data
Nov. 2, 2023 (JP) 2023-188716

(51) Int. Cl. C09J 7/35; C09J 5/06; C09J 7/10; H10W 72/00

(52) U.S. Cl. CPC C09J 7/35; C09J 5/06; C09J 7/10; H10W 72/07338; C09J 2203/326; C09J 2301/304; C09J 2301/414

(57) ABSTRACT

Disclosed is an adhesive composition which contains at least an epoxy resin (A), an epoxy resin curing agent (B), and a polymer component (C). The adhesive composition has a storage elastic modulus after curing of 2,000 MPa or less and a loss tangent after curing of 0.03 or more, and when the compositions are bonded to each other after curing, the bonding strength is 5 MPa or more. The storage elastic modulus and loss tangent after curing are measured under the conditions of a measuring temperature range of 20-300° C., a heating rate of 5° C./min, and a frequency of 1 Hz, after thermally curing the adhesive composition at 180° C. for one hour, thereby obtaining a film-like adhesive piece of 5 mm×17 mm×200 μm. At this time, a measured value at the bonding temperature (any temperature within the range from 25° C. to 300° C. inclusive) is sampled.

### TECHNICAL FIELD

The present invention relates to an adhesive composition, a film-like adhesive and a semiconductor package using the same, and a method for manufacturing the semiconductor package.

### BACKGROUND

As electronic devices advances in downsizing, weight reduction, and high-performance, higher integration of semiconductor chips and the like are in demands. There is, however, a limit to microfabrication of circuits and, in recent years, a method has been proposed for achieving high integration by stacking vertically a plurality of substrates (wafers) and semiconductor chips, etc. to have a multi-layered three-dimensional structure. A 2.XD package, in which each semiconductor chip is housed and mounted on a Si interposer or RDL interposer, is a typical example.

As a method for achieving high integration of substrates and semiconductor chips in such the semiconductor package, bonding via bumps has been conventionally used. To further shorten connection wire distance, however, a method in which copper wirings are directly bonded (direct bonding) will be necessary in the future. As direct bonding connection methods, resin hybrid and inorganic hybrid methods have been considered. There are, however, concerns about foreign matter control and cost in the inorganic hybrid method and thus the resin hybrid method has been attracting attention.

A method in which a composition containing an amide acid cross-linked silane compound, as a direct bonding material for the so-called resin hybrid method, is applied to a wafer by spin coating, and then dried and cured to form a composition of an imide cross-linked siloxane, which is then used for bonding, is known (Japanese Laid-open Patent Application Publication No. 2021-182621 (JP-A-2021-182621) and International Patent Publication No. 2020/085183 (WO/2020/085183), for example).

### SUMMARY OF THE DISCLOSURE

The direct bonding connection method has a problem that adhesive strength after bonding may not be sufficient. This is thought to be due to variation in thickness of the bonding layer and voids contained during bonding. It is estimated that the spin coating method described in the prior art documents has a problem that thickness accuracy varies depending on the number of rotations, material viscosity, drying speed, and the like, resulting in control difficulties and in variation of adhesive strength. Thus, it is an object of the present invention to provide a film-like adhesive and an adhesive composition thereof such that semiconductor wafers can be bonded without voids, thickness variations can be controlled, and sufficient adhesive strength and bonding reliability can be obtained. In addition, it is another object of the present invention to provide a semiconductor package using the film-like adhesive, and a method for manufacturing the semiconductor package.

Inventors of the present invention have tested and verified many of such types of adhesives and adhesive compositions. For test items, a large amount of data including parameters such as physical properties, chemical properties, and physicochemical properties was collected and analyzed. After diligently compiling and verifying the results, it has been discovered that, when made into a film-like adhesive, the above objects can be achieved with a storage elastic modulus of 2,000 MPa or less and a loss tangent of 0.03 or more at a bonding temperature. In addition, requirements are that, when made into the film-like adhesive, good bonding properties are achieved and the bonding strength is 5 MPa or more. Furthermore, it has been discovered that the above objects can be more accurately achieved, as necessary, by setting an epoxy equivalent of an epoxy resin within a suitable range and by setting a blending ratio of a liquid epoxy resin to a solid epoxy resin within a suitable range. The present invention was derived from such findings and includes the following structures.

An adhesive composition containing at least an epoxy resin (A), an epoxy resin curing agent (B), and a polymer component (C), characterized in that, under the following conditions after curing, the adhesive composition has a storage elastic modulus of 2,000 MPa or less and a loss tangent of 0.03 or more, and when the compositions are bonded to one another after curing, bonding strength under the following conditions is 5 MPa or more. The conditions are: the storage elastic modulus and loss tangent after curing are measured under conditions of a measuring temperature range of 20 to 300° C., a heating rate of 5° C./min, and a frequency of 1 Hz, after thermally curing the adhesive composition at 180° C. for one hour, thereby obtaining a film-like adhesive piece of 5 mm×17 mm×200 μm, and at this time, measured values at a bonding temperature below are sampled; the bonding temperature is any temperature of 25° C. or more and 300° C. or less; and the bonding strength is the strength required to peel and separate at room temperature two chips attached with film-like adhesives, each film-like adhesive being made to have a thickness of 1.0 μm by heating the adhesive composition at 180° C. for one hour followed by thermal curing and the two chips being bonded together at the bonding temperature by butting against each other the film-like adhesives of both.

The adhesive composition according to (1) characterized in that an epoxy equivalent of the epoxy resin (A) used in the adhesive composition is 300 g/eq or more, and content of the epoxy resin (A) is 20 mass % or more of a total amount of the epoxy resin (A), the epoxy resin curing agent (B), and the polymer component (C).

The adhesive composition according to (1) characterized in that the epoxy resin (A) is a blend of an epoxy resin that is liquid at room temperature and an epoxy resin that is solid at room temperature, wherein content of the liquid epoxy resin is 100 to 250 parts by mass and content of the solid epoxy resin is 15 to 90 parts by mass when content of the polymer component (C) is 100 parts by mass, and mass ratio of the solid epoxy resin to the liquid epoxy resin is in a range of 1:10 to 6:10.

The adhesive composition according to (1) characterized in that the epoxy resin curing agent (B) is an imidazole-based curing agent.

The adhesive composition according to (1) characterized in that the bonding temperature is 25° C. or more and 200° C. or less.

A film-like adhesive made by heat treating the adhesive composition according to any one of (1) to (5).

The film-like adhesive according to (6) may have a thickness of 0.1 to 50 μm.

A method for manufacturing a semiconductor package including adhering and thermally curing the film-like adhesive according to (6) onto a semiconductor wafer having at least one semiconductor circuit formed on a surface thereof to provide an adhesive layer, and bonding and stacking the semiconductor wafers via the adhesive layers by compressing the adhesive layers at room temperature or through thermal curing to form a resin curing body that can bond the semiconductor wafers to be multi-layered.

The method for manufacturing a semiconductor package according to (8) further including flattening the adhesive layer such that the terminals are exposed from the adhesive layer and a surface of the adhesive layer and surfaces of the terminals are flush with each other.

A semiconductor package including semiconductor wafers bonded by the resin curing body of the film-like adhesives according to (6).

A film-like adhesive made by heat treating an adhesive composition containing at least an epoxy resin (A), an epoxy resin curing agent (B), and a polymer component (C). Under the following conditions, the film-like adhesive has a storage elastic modulus of 2,000 MPa or less and a loss tangent of 0.03 or more, and bonding strength when bonded under the following conditions is 5 MPa or more. The conditions are: the storage elastic modulus and loss tangent are measured under conditions of a measuring temperature range of 20 to 300° C., a heating rate of 5° C./min, and a frequency of 1 Hz, after thermally curing the adhesive composition at 180° C. for one hour, thereby obtaining a film-like adhesive piece of 5 mm×17 mm×200 μm, and at this time, measured values at a bonding temperature below are sampled; the bonding temperature is any temperature of 25° C. or more and 300° C. or less; and the bonding strength is the strength required to peel and separate at room temperature two chips attached with film-like adhesives, each film-like adhesive being made to have a thickness of 1.0 μm and the two chips being bonded together at the bonding temperature by butting against each other the film-like adhesives of both.

According to the present invention, an adhesive composition and a film-like adhesive thereof, semiconductor wafers can be bonded without voids, thickness variations can be controlled, and sufficient adhesive strength and bonding reliability can be obtained. In addition, a semiconductor package using the film-like adhesive according to the present invention has high quality and excellent performance reliability. Furthermore, according to a method for manufacturing the semiconductor package of the present invention, the semiconductor package including the above film-like adhesive can be suitably manufactured.

### BRIEF DESCRIPTION OF DRAWINGS

FIG. 1 is a flowchart showing a process of producing and applying a film-like adhesive.

FIG. 2A is a cross-sectional view schematically showing a step (a) of manufacturing a semiconductor wafer according to an embodiment of the present invention.

FIG. 2B is a cross-sectional view schematically showing a step (b) of manufacturing the semiconductor wafer according to the embodiment of the present invention.

FIG. 2C is a cross-sectional view schematically showing a step (c) of manufacturing the semiconductor wafer according to the embodiment of the present invention.

FIG. 2D is a cross-sectional view schematically showing a step (d) of manufacturing the semiconductor wafer according to the embodiment of the present invention.

FIG. 2E is a cross-sectional view schematically showing a step (e) of manufacturing the semiconductor wafer according to the embodiment of the present invention.

FIG. 2F is a cross-sectional view schematically showing a step (f) of manufacturing the semiconductor wafer according to the embodiment of the present invention.

FIG. 3 is a cross-sectional view showing schematically a flattening step by polishing that is employed in a flattening process (d) in FIG. 2.

FIG. 4 is a side view showing schematically a state in which two substrates attached with the film-like adhesives are bonded together by butting the film-like adhesives against each other.

FIG. 5 is a photograph, used as a substitute for a drawing and taken as a microscope image, of a side view of the film-like adhesives bonded together.

FIG. 6 is a side view showing schematically an apparatus and a measurement form for measuring die-shear strength.

### DETAILED DESCRIPTION

An adhesive composition according to the present invention is characterized in that the adhesive composition contains at least an epoxy resin (A), an epoxy resin curing agent (B), and a polymer component (C) and has a storage elastic modulus of 2,000 MPa or less and a loss tangent of 0.03 or more after curing, and when the compositions are bonded to one another after curing, bonding strength is 5 MPa or more. Hereinafter, the present invention will be described in detail, focusing on preferred embodiments and examples, with reference to the accompanying drawings as necessary.

In the adhesive composition of the present invention, values of storage elastic modulus and loss tangent after curing are measured when made into a film-like adhesive piece of 5 mm×17 mm×200 μm. A measuring temperature (a sampling temperature) is a bonding temperature. The bonding temperature is a temperature at which substrates or the like are bonded via the film-like adhesive, and is preferably 25° C. or more and 300° C. or less, and typically within a range between room temperature (25° C.) and 200° C. The storage elastic modulus (E′) is 2,000 MPa or less, and, under a condition of the bonding temperature of 25° C. (except when no filler is included), the storage elastic modulus is preferably 1,800 MPa or less, and more preferably 1,600 MPa or less. Although there is no particular limit, it is practical to set a lower limit to 1,000 MPa or more. Under a condition that the bonding temperature is 200° C. or the filler is not included, the storage elastic modulus is preferably 200 MPa or less, more preferably 150 MPa or less, and even more preferably 100 MPa or less. Although there is no particular limit, the lower limit is preferably 1 MPa or more, more preferably 2 MPa or more, and even more preferably 5 MPa or more.

The adhesive composition of the present invention has, in a form of the film-like adhesive after curing, the loss tangent of 0.03 or more, and the loss tangent is preferably 0.04 or more, or more preferably 0.05 or more. Although there is no particular limit, it is practical to set an upper limit to 1.0 or less. The film-like adhesive after curing refers to a film-like adhesive that has been treated under conditions of Heat Treatment 2 or Heat Treatment 3 that will be described below.

The adhesive composition of the present invention has the above storage elastic modulus and loss tangent in the form of a cured film-like adhesive. This not only makes it easier to handle but also makes it less likely to form voids etc. on a bonding interface that tends to be repulsive, thereby exhibiting excellent bonding performance. Also, a surface of the substrate may have unevenness due to terminals and the like. There had been a concern that the film-like adhesive would not be able to follow such an outer shape. However, by adjusting the storage elastic modulus E′ and the tangent loss tan δ to be within the above suitable ranges when made into the film-like adhesive, the adhesive shows just the right followability and viscosity with respect to the substrate and also suppresses voids from forming at the protruding terminal parts. Here, the storage elastic modulus mainly refers to stability and flexibility of the shape, and defines a range in which such the stability and flexibility of the shape are not lost. The loss tangent mainly represents a relationship with viscosity, and, if the loss tangent is equal to or more than a certain value, the adhesive exhibits properties that the adhesive deforms and follows the unevenness of the substrate with a delay.

The adhesive composition of the present invention has, after curing, the bonding strength of 5 MPa or more, preferably 10 MPa or more, more preferably 15 MPa or more, more preferably 20 MPa or more, more preferably 25 MPa or more, more preferably 30 MPa or more, and even more preferably 35 MPa or more. The higher the bonding strength is, the stronger bonding with a semiconductor chip can be obtained. The bonding strength is the strength required to peel off, at room temperature (25° C.), a dummy chip with a cured film-like adhesive from another dummy chip with a cured film-like adhesive, which have been bonded at the bonding temperature by being butted against each other at adhesive surfaces. Although there is no particular limit, it is practical to set an upper limit of the bonding strength to 100 MPa or less.

The bonding temperature can be defined as temperature at which substrates are bonded via the film-like adhesive, which is formed by curing the adhesive composition at 180° C. for one hour, for example. Although not particularly limited to a specific temperature, it is preferable that the bonding temperature is between 25° C. and 300° C., and more preferably between 25° C. and 200° C. In the preferred embodiments of the present invention, it is sufficient if the predetermined conditions (E′, tan δ, and the bonding strength) are satisfied at any of the above bonding temperatures, and it is preferable that the predetermined conditions are satisfied at least either at 300° C. (preferably 200° C.) or 25° C. It is more preferable that the predetermined conditions are satisfied at least at 300° C. (preferably 200° C.), and it is even more preferable that the predetermined conditions are satisfied also at 25° C. In particular, bonding at room temperature is preferable because it is less likely to cause misalignment.

Samples to be used for measuring each parameter may be prepared as appropriate. In the present invention, it is preferable to use samples that have been heat treated under the following conditions:
When the bonding temperature is room temperature (25° C.) and when measuring viscoelastic properties: Heat Treatment 1 [130° C. 1.5 minutes]*¹, Heat Treatment 2 [70° C. pressure: 0.3 MPa]*¹ 180° C. 1 hour;
When the bonding temperature is 200° C.: Heat Treatment 1 [130° C. 1.5 minutes]*¹, Heat Treatment 2 [70° C. pressure: 0.3 MPa]*¹ 180° C. 1 hour, Heat Treatment 3 200° C., 10 N/40 N*², 10 seconds;
*1 [ ] may be omitted;
*2 10 N for die-shear strength measurement and 40 N for evaluation on bonding properties.

### (Epoxy Resin (A))

The adhesive composition of the present invention contains the epoxy resin (A), the epoxy resin curing agent (B), and the polymer component (C). The epoxy resin (A) can be classified into those that are solid and those that are liquid at room temperature (25° C.). In the adhesive composition of the present invention, a blend of the solid epoxy resin and liquid epoxy resin or the liquid epoxy resin alone is preferable, and among the above, the blend of the solid epoxy resin and liquid epoxy resin is more preferable. When only the liquid epoxy resin is used, tackiness may be too strong and handling may become difficult. Also, if the blend of the two is used, it is possible to easily achieve both appropriate followability and shape stability. Specific examples of the epoxy resin include solid BisA-type epoxy resin, liquid flexible epoxy resin, and liquid BisA-type epoxy resin. A combination of the solid BisA-type epoxy resin and the liquid flexible epoxy resin is preferable above all.

Whether the epoxy resin is liquid or solid can be defined by viscosity of the epoxy resin at room temperature (25° C.). It is preferable that the liquid epoxy resin has viscosity of 50 Pa·s or less, more preferably 40 Pas or less, and even more preferably 30 Pa·s or less. Although there is no particular limit, a lower limit is preferably 0.5 Pas or more, more preferably 0.8 Pa·s or more, and even more preferably 1.0 Pa·s or more. As for an upper limit, if the viscosity of the liquid epoxy resin is within such the range, the epoxy resin has appropriate fluidity, resulting in easy process, and followability to the unevenness of the substrates when formed into the film-like adhesive. The viscosity of the solid epoxy resin, on the other hand, is more than 50 Pa·s. The viscosity was measured by a method that conforms to JIS Z8803: 2011-8, which is a viscosity measuring method using a coaxial double cylindrical rotational viscometer. As a measuring apparatus, a precision rotational viscometer RSX-CC (manufactured by Eiko Instruments Co., Ltd.) was used.

An epoxy equivalent of the epoxy resin (A) is preferably 200 g/eq or more, more preferably 300 g/eq or more, and even more preferably 350 g/eq or more. Although there is no particular upper limit, it is practical that the upper limit is 1000 g/eq or less. With the epoxy equivalent of the epoxy resin (A) within the above range, the film-like adhesive has appropriate flexibility and suitable adhesive properties, and exhibits excellent performance in bonding properties and die-shear strength.

Molecular weight of the solid epoxy resin is, though there is no particular limit, preferably 700 or more, more preferably 800 or more, and even more preferably 900 or more. An upper limit thereof is preferably 2,000 or less, more preferably 1,500 or less, and even more preferably 1,200 or less. With the molecular weight of the solid epoxy resin within such the range, it is possible to obtain the film-like adhesive that is easy to maintain its shape, is not too hard, and has appropriate elasticity. Molecular weight of the liquid epoxy resin is, though there is no particular limit, preferably more than 400, more preferably 450 or more, and even more preferably 470 or more. Although there is no particular limit, an upper limit thereof is preferably 800 or less, more preferably 700 or less, and even more preferably 650 or less. The liquid epoxy resin having the molecular weight within the above range is preferred in that it is possible to achieve appropriate flexibility of the film-like adhesive, particularly when combined with the solid epoxy resin. Table 1 below shows specifications of the epoxy resin used in Working Examples.

Unless otherwise specified in the present description, the molecular weight is a value (weight average molecular weight) calculated in terms of polystyrene using GPC (Gel Permeation Chromatography). Although no particular conditions are specified, tetrahydrofuran may be used as a carrier during measurement, two TSKgel GMHXL columns and one G2500HXL column (φ7.8 mm×30 cm, manufactured by Tosoh Corporation) may be used as columns, with a flow rate of 1 mL/min, a column temperature of 40° C., and an inflow of 0.2 mL, for example. However, those with the low molecular weight that are difficult to be measured by GPC may be identified using a mass spectrometer (MS).

TABLE 1

| Epoxy | Viscosity (Room | Epoxy | Molecular | Softening |
|---|---|---|---|---|
| Resin | Temperature) | Equivalent | Weight | Point |
| YD-012 | (Solid) | 655 g/eq | 1,000 | 81° C. |
| YX-7105 | 10.0 Pa · s | 487 g/eq | 600 | 25° C. or less |
| AER9000 | 1.2 Pa · s | 375 g/eq | 500 | 25° C. or less |
| YD-128 | 13.0 Pa · s | 189 g/eq | 400 | 25° C. or less |

A softening point of the solid epoxy resin is, though there is no particular limit, preferably 60° C. or more, more preferably 70° C. or more, and even more preferably 75° C. or more. An upper limit thereof is preferably 100° C. or less, more preferably 90° C. or less, and even more preferably 85° C. or less. The solid epoxy resin having the softening point within the above range is preferred in that, when blended with the liquid epoxy resin, the film-like adhesive does not flow or deform. A softening point of the liquid epoxy resin is preferably 40° C. or less, more preferably 35° C. or less, and even more preferably 30° C. or less. The liquid epoxy resin having the softening point within the above range is preferred in that it is possible to obtain the shape stability of the film-like adhesive and the followability thereof to the substrates when blended with the solid epoxy resin.

In the present specification, the softening point refers to a measured value based on the softening point test (ring and ball method) (measurement conditions: in accordance with JIS-K7234-1986).

An example of the epoxy resin that can be used in the present invention is shown below. However, the example is not to be construed as limiting the present invention. n represents an integer, and is preferably 0 to 2, and R is a hydrogen atom or a methyl group.

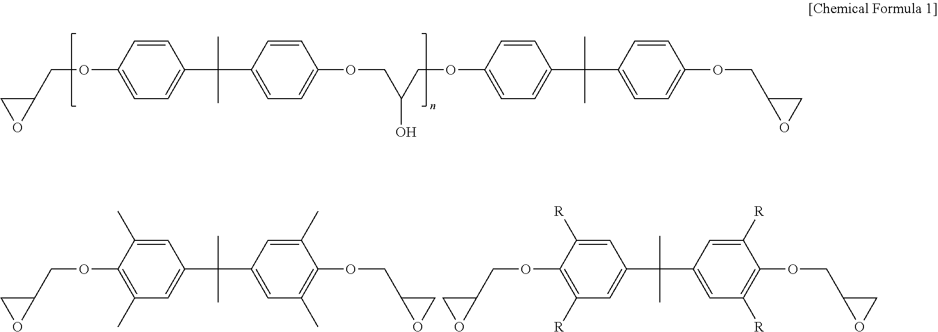

In the adhesive composition of the present invention, a blending amount of the epoxy resin (solid and liquid combined) is, when the polymer component (C) is 100 parts by mass, preferably 150 parts by mass or more, more preferably 175 parts by mass or more, and even more preferably 190 parts by mass or more. An upper limit thereof is preferably 250 parts by mass or less, more preferably 230 parts by mass or less, and even more preferably 210 parts by mass or less. With the epoxy resin blended within such the range, it is preferred in that sufficient adhesive strength can be maintained while achieving shape stability.

The blending amount of the epoxy resin (A) to the total of the epoxy resin (A), the epoxy resin curing agent (B), and the polymer component (C) is preferably 20 mass % or more, more preferably 30 mass % or more, and even more preferably 40 mass % or more. An upper limit thereof is preferably 90 mass % or less, more preferably 80 mass % or less, and even more preferably 70 mass % or less.

When a filler is contained, the blending amount of the epoxy resin (A) to the total amount of the adhesive composition is preferably 20 mass % or more, more preferably 25 mass % or more, and even more preferably 30 mass % or more. An upper limit thereof is preferably 60 mass % or less, more preferably 50 mass % or less, and even more preferably 40 mass % or less. When no filler is contained, the blending amount of the epoxy resin (A) to the total amount of the adhesive composition is preferably 40 mass % or more, more preferably 50 mass % or more, and even more preferably 60 mass % or more. An upper limit thereof is preferably 80 mass % or less, more preferably 75 mass % or less, and even more preferably 70 mass % or less.

The adhesive composition of the present invention is preferably a blend of a liquid epoxy resin (particularly a liquid flexible epoxy resin, sometimes referred to as a stress-relieving epoxy resin) and a solid resin. When the epoxy resin (A) is a blend of an epoxy resin that is liquid at room temperature and an epoxy resin that is solid at room temperature, a blending amount of the liquid epoxy resin per 100 parts by mass of the polymer component (C) is preferably 100 to 250 parts by mass, more preferably 115 to 200 parts by mass, and even more preferably 120 to 180 parts by mass. For the solid epoxy resin, a content per 100 parts by mass of the polymer component (C) is preferably 15 to 90 parts by mass, more preferably 20 to 80 parts by mass, and even more preferably 25 to 70 parts by mass. A mass ratio of the solid epoxy resin to the liquid epoxy resin is preferably within a range of 0.5:10 to 9:10, more preferably within a range of 0.75:10 to 8:10, even more preferably within a range of 1:10 to 6:10, and even furthermore preferably within a range of 1.5:10 to 4.5:10.

A content rate of the stress-relieving epoxy resin (liquid flexible epoxy resin) to the total resin of the epoxy resin (A) and the polymer component (C) is preferably 20 mass % or more, more preferably 30 mass % or more, and even more preferably 40 mass % or more. An upper limit thereof is preferably 70 mass % or less, more preferably 60 mass % or less, and even more preferably 50 mass % or less. Here, the liquid flexible epoxy resin is typically an epoxy resin that maintains a flexible skeleton at parts indicated by broken lines shown in the structure below. This provides stress-relieving capability. This indirectly has the effect of lowering the storage elastic modulus, which is an important parameter in the present invention, and of increasing the loss tangent. With such action, it is possible to obtain the film-like adhesive that can control variation in thickness and has sufficient adhesive strength and bonding reliability.

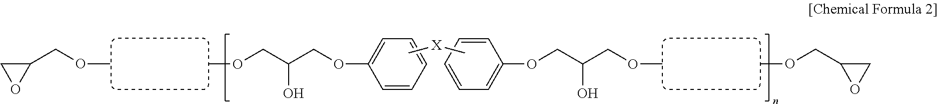

When the solid epoxy resin and the liquid epoxy resin are blended within the above range, it is preferred in that the shape stability when formed into the film-like adhesive can be obtained, while having flexibility that allows the adhesive to follow and adhere to the unevenness of the substrate. It is also preferable to be in the above range in terms of achieving excellent adhesive properties when made into the film-like adhesive. Furthermore, due to moderate adhesiveness, handling during manufacture is good.

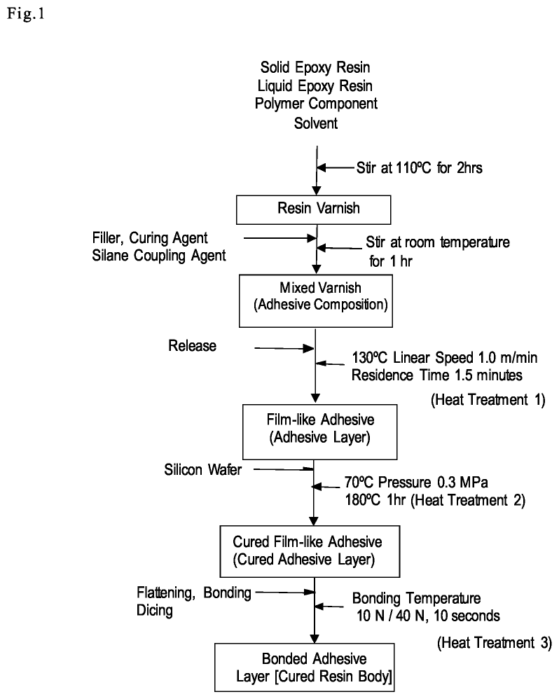

The adhesive composition of the present embodiment is intended to be formed into a film and applied to a substrate. Although there is no particular limit to conditions under which the adhesive composition are converted into a film-like adhesive, for example, essential components may be dissolved in a solvent to form a softened varnish or mixed varnish, which is then heated at a predetermined temperature for a predetermined time to evaporate the solvent, thereby obtaining a film-like adhesive (see FIG. 1, Heat Treatment 1). In the present embodiment, such the film-forming process and a subsequent heat-curing process (Heat Treatment 2) are employed, and through such processes, it is possible to achieve an adhesive layer with a uniform surface with less unevenness, which cannot be achieved by liquid adhesives. In other words, it is important to select the component composition of the adhesive composition that is to be formed into a film in the above film-forming process. The above-mentioned heat treatment processes will be described in detail below in the description of the manufacturing method.

The epoxy resin (A) may be used alone or in combination of two or more types. When two or more types are used, the total amount falls within the above range.

### (Epoxy Resin Curing Agent (B))

As a curing agent for the epoxy resin, conventionally used ones can be used. Examples include amines (aliphatic amines, aromatic amines, or modified amines), polyamide resin, tertiary and secondary amines, imidazoles, polymercaptan curing agents, liquid polymercaptan, polysulfide resin, and acid anhydrides. In the present invention, imidazoles are particularly preferred. Examples of imidazole-based curing agents include the following compounds. A compound (e) is preferable among the followings. R in the formulae refers to a hydrogen atom or an organic group.

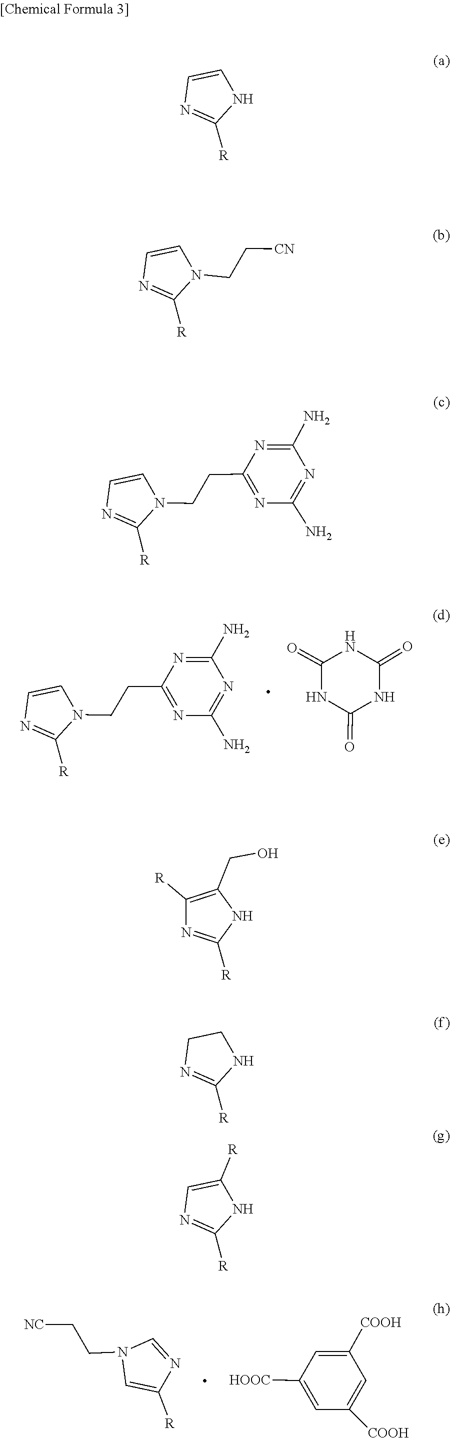

A blending amount of the epoxy resin curing agent (B) may be determined appropriately depending on an amount of the epoxy resin. For example, per 100 parts by mass of the polymer component (C), the blending amount of the epoxy resin curing agent (B) is preferably 0.5 to 10 parts by mass, more preferably 1 to 6 parts by mass, and even more preferably 2 to 4 parts by mass. By blending the epoxy resin curing agent (B) within the above range, it is preferred in that the epoxy resin reacts appropriately and is cross linked.

The epoxy resin curing agent (B) may be used alone or in combination of two types or more. When two or more types are used, the total amount falls within the above range.

### (Polymer Component (C))

The polymer component (C) is a component that forms a base skeleton when the adhesive composition of the present invention is made into a film-like adhesive. A content of the polymer component (C) is, when the total of the epoxy resin (A), the epoxy resin curing agent (B), and the polymer component (C) is 100 mass %, preferably 5 to 50 mass %, more preferably 10 to 45 mass %, and even more preferably 15 to 40 mass %. There is no limitation in use for the polymer constituting the polymer component, and examples include BisA-type phenoxy resin, urethane resin, and acrylic resin. Although there is no particular limit for the molecular weight of the polymer component, examples are those with the molecular weight of 20,000 to 1,000,000, and compounds with the molecular weight of 35,000 to 800,000 are preferable, or compounds with the molecular weight of 50,000 to 600,000 are more preferable. By making the molecular weight of the polymer component (C) equal to or more than the above lower limit, it is possible to obtain stabilized shape when made into the film-like adhesive. By making the molecular weight of the polymer component (C) equal to or less than the above upper limit, it is possible to obtain flexibility that exhibits followability to the shape of the unevenness (terminals) of the substrate surface and suitable adhesiveness. The method for measuring the molecular weight is as described above.

The polymer component (C) may be used alone or in combination of two types or more. When two or more types are used, the total amount falls within the above range.

### (Filler)

In the adhesive composition of the present invention, silica, talc, calcium carbonate, etc. can be introduced as a filler if necessary, and among the above, it is preferable to use silica as the filler. This makes it possible to increase the storage elastic modulus in particular, and to obtain good shape stability when made into the film-like adhesive. Although there is no particular limit, a blending amount of the filler is, when the total of the adhesive composition is 100 mass %, preferably 15 mass % or more and 80 mass % or less, more preferably 20 mass % or more and 70 mass % or less, and even more preferably 25 mass % or more and 65 mass % or less.

The filler may be used alone or in combination of two types or more. When two or more types are used, the total amount falls within the above range.

### (Silane Coupling Agent)

A silane coupling agent is a compound that bonds with the filler (e.g., silica) to achieve stability within the system, and thus the silane coupling agent may be selected taking into consideration an amount and type of the filler to be added. Also, since the adhesive composition of the present invention uses the epoxy resin, it is preferable to have affinity thereto. For such reasons, the silane coupling agent used in the adhesive composition of the present invention is preferably an epoxy silane type silane coupling agent. Specifically, a compound in which an epoxy group (oxirane group) is introduced at one or both ends of a polysiloxane is preferable. A blending amount of the silane coupling agent is, per 100 parts by mass of the polymer component (C), preferably 0.5 to 6 parts by mass, more preferably 0.8 to 4 parts by mass, and even more preferably 1 to 3 parts by mass. The silane coupling agent within such the range is preferred in that other performances are not affected and silica particles as the filler remain within the system, thereby preventing uneven distribution or falling off of the silica.

The silane coupling agent may be used alone or in combination of two types or more. When two or more types are used, the total amount falls within the above range.

### (Solvent)

A solvent used in the adhesive composition of the present invention is, though there is no particular limit, a solvent that can dissolve or disperse the above-mentioned components, namely, the epoxy resin (A), the epoxy resin curing agent (B), and the polymer component (C). The solvent is preferably an organic solvent, such as alcohols, ketones (methyl ethyl ketone (MEK), acetone, etc.), cyclic or chain hydrocarbons (e.g., cyclohexane, etc.), aldehydes, and carbonates (dimethyl carbonate, etc.). Although there is no particular limit for a boiling point of the organic solvent, from viewpoint of not transpiring at room temperature but transpiring suitably in Heat Treatment 1 mentioned above, the boiling point is preferably 50° C. or more, more preferably 60° C. or more, and even more preferably 70° C. or more. An upper limit thereof is preferably 120° C. or less, more preferably 110° C. or less, and even more preferably 100° C. or less. The solvent may be used alone or in combination of two types or more.

### (Method for Manufacturing Film-Like Adhesive and Semiconductor Package)

The film-like adhesive of the present invention is obtained from an adhesive composition having the above-mentioned component composition. FIG. 1 shows an example of a manufacturing process of the film-like adhesive and a process for forming an adhesive layer in which the film-like adhesives are bonded. Although there is no particular limitation to a method for forming the adhesive composition into the film-like adhesive, an example includes an embodiment of preparing varnish having required components or mixed varnish added with a filler, which is then heated on a release film or the like for a predetermined time. Heating temperature for such Heat Treatment 1 is preferably 80° C. to 150° C., more preferably 90° C. to 140° C., and even more preferably 100° C. to 135° C. Heating time (residence time) is preferably 10 seconds to 30 minutes, more preferably 20 seconds to 20 minutes, and even more preferably 30 seconds to 15 minutes. If the adhesive composition is heated excessively when being formed into the film-like adhesive, adhesiveness of the subsequent film-like adhesive may become poor. If heating is insufficient, on the other hand, surface shape may not be stabilized and there may be problems in bonding properties and adhesive strength. A thickness of the film-like adhesive is preferably 0.1 μm or more, more preferably 0.5 μm or more, and even more preferably 0.75 μm or more. An upper limit thereof is preferably 50 μm or less, more preferably 40 μm or less, and even more preferably 30 μm or less.

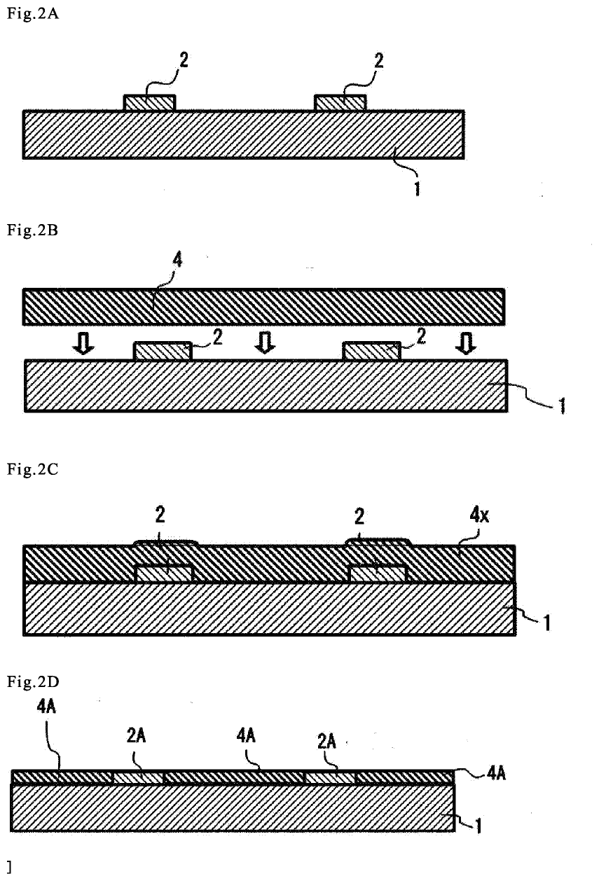

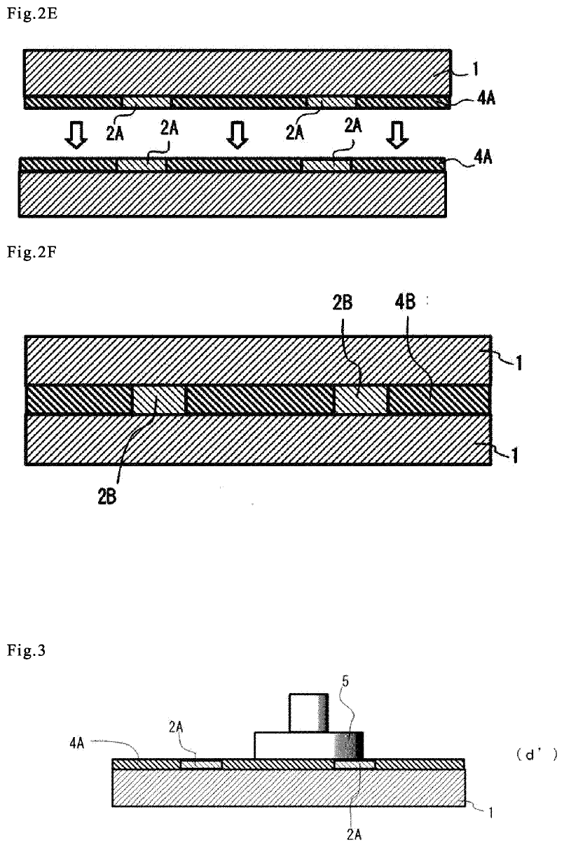

A method including processes shown in FIG. 2 and FIG. 3 is an example of a method for manufacturing a package including a semiconductor wafer (in the present description, “semiconductor wafer” is used to mean to include “semiconductor substrate”) using the film-like adhesive of the present invention. Firstly, a semiconductor wafer formed with at least one semiconductor circuit on a surface thereof is prepared (step a). A film-like adhesive shaped from the adhesive composition is prepared (step b). The heating temperature and time for shaping (Heat Treatment 1) at this time are as mentioned above. The film-like adhesive of the present invention is thermocompression bonded onto the surface of the prepared semiconductor wafer on which the semiconductor circuit is formed so as to provide an adhesive layer (step c). For conditions for the thermocompression bonding, temperature is preferably 50° C. or more and 100° C. or less, more preferably 60° C. or more and 90° C. or less, and even more preferably 65° C. or more and 80° C. or less; pressure is preferably 0.05 MPa or more and 2 MPa or less, more preferably 0.1 MPa or more and 1.5 MPa or less, and even more preferably 0.2 MPa or more and 1 MPa or less; and pressurization time is preferably 10 seconds or more and 10 minutes or less, more preferably 30 seconds or more and 8 minutes or less, and even more preferably 1 minute or more and 6 minutes or less. The manufacturing method of the present embodiment includes a subsequent heating step of Heat Treatment 2. Temperature for the heating step of Heat Treatment 2 is preferably 150° C. or more and 210° C. or less, more preferably 160° C. or more and 200° C. or less, and even more preferably 170° C. or more and 190° C. or less. Heating time is preferably 30 minutes or more and 90 minutes or less, more preferably 40 minutes or more and 80 minutes or less, and even more preferably 50 minutes or more and 70 minutes or less. Through the above thermocompression and heating steps, the adhesive layer is cured to an appropriate degree to be a cured resin, which has excellent shape stability while retaining adhesiveness thereof. After the shape stabilization of the adhesive layer, a flattening process is performed such that terminals are exposed from the adhesive layer (a cured film-like adhesive 4x) and the surface of the adhesive layer and surfaces of the terminals are flush with each other (steps d and d′). In a working example of FIG. 3, the adhesive layer and the terminals are polished with a polishing pad 5 using CMP (Chemical Mechanical Planarization) to form a flat surface (a flattened adhesive layer 4A and flattened surfaces of the terminals 2A). After CMP is performed, abrasives (slurry) used therein is washed away and removed. Note that the steps d and d′ may be omitted if an adhesive layer that fits the unevenness of the terminals etc. is to be formed. Next, two semiconductor wafers each attached with the adhesive layer are prepared, and the film-like adhesive layers thereof are bonded together to form a multi-layered structure (steps e and f). In FIG. 2, a bonded adhesive layer (cured resin body) 4B and bonded terminals 2B are formed. The bonding temperature at this time is as mentioned above, and is preferably between room temperature (25° C.) and 200° C., and more preferably room temperature (25° C.) or 200° C. If the temperature is 200° C., the present step is Heat Treatment 3. If the bonding temperature is room temperature, the previous step of Heat Treatment 2 is the last heat treatment step before bonding. Through the above steps, it is possible to obtain a semiconductor package formed of the semiconductor wafers bonded together by the cured resin body of the film-like adhesive.

When the bonding step is a heat treatment step, the temperature is preferably 160° C. or more and 240° C. or less, more preferably 170° C. or more and 230° C. or less, and even more preferably 175° C. or more and 220° C. or less. Although there is no particular limit, the compression force is preferably 2 N or more and 80 N or less, more preferably 4 N or more and 60 N or less, and even more preferably 6 N or more and 50 N or less. Although there is no particular limit, the heating time is preferably 1 second or more and 60 seconds or less, more preferably 5 seconds or more and 50 seconds or less, and even more preferably 7 seconds or more and 30 seconds or less.

Hereinafter, the present invention will be described more specifically based on Working Examples and Comparative Examples. However, the present invention is not limited to the following examples. In particular, the embodiments shown in FIG. 1 to FIG. 6 are merely examples of the embodiments of the present invention, and the present invention is by no means limited to those shown in the drawings. In each of Working Examples and Comparative Examples, evaluation on storage elastic modulus, loss elastic modulus, loss tangent tan δ at the bonding temperature, evaluation on bonding properties, and evaluation on die-shear strength are conducted by the following methods, respectively.

### WORKING EXAMPLES

### Measurement Example 1

### (Storage Elastic Modulus, Loss Elastic Modulus, and Loss Tangent Tan δ at the Bonding Temperature)

Using each adhesive composition obtained in each Working and Comparative Example, a single-layered film, in which a film-like adhesive having a length of 300 mm, width of 200 mm, and thickness of 200 μm is formed on a release film, was obtained using a multi-coater. A cured film-like adhesive obtained by curing such a sample at 180° C. for 1 hour was cut into a size of 5 mm×17 mm (thickness 200 μm), the release film was peeled off, and a dynamic viscoelasticity measuring device (product name: Rheogel-E4000F, manufactured by UBM Co., Ltd.) was used under conditions (tensile mode) of a measurement temperature range of 20 to 300° C., a heating rate of 5° C./min, and a frequency of 1 Hz, to measure the storage elastic modulus and loss elastic modulus at each temperature. The storage elastic modulus and loss elastic modulus at the bonding temperature were read. Numerical values of the loss tangent tan δ were calculated by Formula 1 below (in accordance with JISK7244 (formerly K7198: 1991)).

Loss tangent tan δ=loss elastic modulus+storage elastic modulus Formula 1

### Measurement Example 2

### (Evaluation on Bonding Properties)

The film-like adhesive with a release film obtained in each Working Example and Comparative Example was first adhered to one surface of a dummy silicon wafer (8 inch size, 365 μm thick) at a temperature of 70° C. and a pressure of 0.3 MPa using a manual laminator (product name: FM-114, manufactured by Technovision, Inc.). The release film is peeled off from the film-like adhesive, which is then cured at 180° C. for 1 hour in a heating oven. For the wafer with the film-like adhesive that had been heat-treated in this way, a dicing tape (product name: K-13, manufactured by Furukawa Electric Co., Ltd.) and a dicing frame (product name: DTF2-8-1H001, manufactured by DISCO CORPORATION) were adhered to a surface of the cured film-like adhesive opposite to the dummy silicon wafer with the cured film-like adhesive at room temperature and pressure of 0.3 MPa using a manual laminator (product name: FM-114, manufactured by Technovision, Inc.). Next, a dicing device (product name: DFD-6340 (manufactured by DISCO CORPORATION) equipped with two-axis dicing blades (Z1: NBC-ZH2050 (27HEDD), manufactured by DISCO CORPORATION/Z2: NBC-ZH127F-SE (BC), manufactured by DISCO CORPORATION) was used to perform dicing from the dummy silicon wafer side to a size of 10 mm×10 mm to obtain a dummy chip with the cured film-like adhesive (the thickness of the adhesive: 1.0 μm).

Using the film-like adhesive with release film obtained in each Working Example and Comparative Example in the similar processing method, dicing was performed from the dummy silicon wafer side to a size of 12 mm×12 mm to obtain a dummy chip with the cured film-like adhesive (thickness of the adhesive: 1.0 μm).

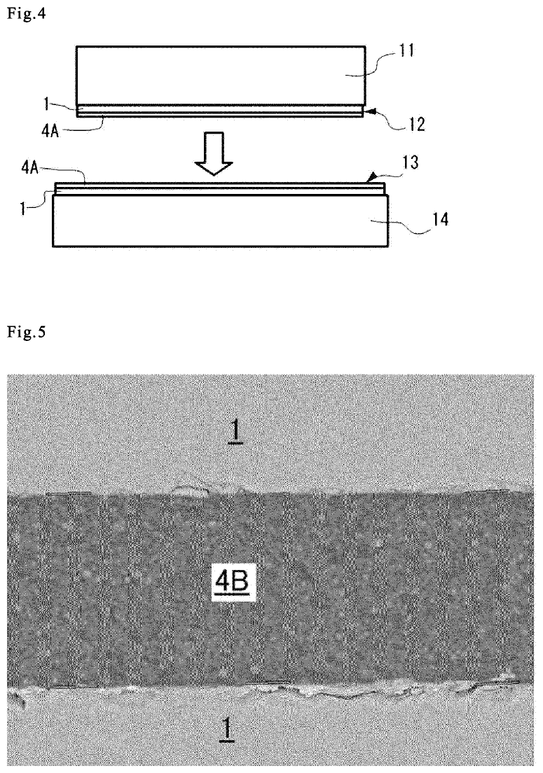

Next, using a flip chip bonder (product name: TFC Z100C, manufactured by Shibaura Mechatronics Corporation), the 10 mm×10 mm dummy chip with the cured film-like adhesive (test substrate) 12 (FIG. 4) was picked up from the dicing tape and mounted on the 12 mm×12 mm dummy chip with the cured film-like adhesive (test substrate) 13 installed on a stage so that the film-like adhesives were bonded to each other. The mounting conditions at this time were as follows. Note that when temperature of a collet 11 was raised to 200° C., temperature of the stage 14 was also raised to 150° C.
Collet 11 temperature: room temperature (25° C.) or 200° C.;
Stage 14 temperature: room temperature (25° C.) or 150° C.;
Bonding pressure: 40 N;
Bonding time: 10 seconds.

For the bonded dummy chips, presence or absence of voids at an interface between the cured film-like adhesives at room temperature (25° C.) was observed using an ultrasonic flaw detector (SAT) (FS300III manufactured by Hitachi Power Solutions, Co., Ltd.), and bonding properties were evaluated based on the following evaluation criteria. In this test, an evaluation rank of “A” is a passing level.

### Evaluation Criteria

AA: No voids were observed in all of the 100 implemented dummy chips;
A: No voids were observed in all of the 24 implemented dummy chips;
B: Voids were observed in one or more and three or less dummy chips out of the 24 implemented dummy chips;
C: Voids were observed in 4 or more dummy chips out of the 24 implemented dummy chips.

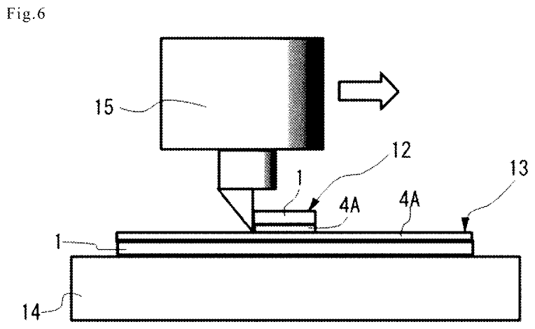

As an example, a microscope image of FIG. 5 is a cross-sectional view of the bonding interface. It can be seen that the interface between the two film-like adhesives has disappeared and a highly adhesive state has been obtained. No voids are observed.

### Measurement Example 3

### (Evaluation on Die-Shear Strength)

A film-like adhesive with a release film obtained in each Working Example and Comparative Example was first adhered to one surface of a dummy silicon wafer (8 inch size, 365 μm thick) at a temperature of 70° C. and a pressure of 0.3 MPa using a manual laminator (product name: FM-114, manufactured by Technovision, Inc.). The release film is peeled off from the film-like adhesive, which is then cured at 180° C. for one hour in a heating oven. For the wafer with the cured film-like adhesive, a dicing tape (product name: K-13, manufactured by Furukawa Electric Co., Ltd.) and a dicing frame (product name: DTF2-8-1H001, manufactured by DISCO CORPORATION) were adhered to a surface of the film-like adhesive opposite to the dummy silicon wafer with the cured film-like adhesive at room temperature and pressure of 0.3 MPa using a manual laminator (product name: FM-114, manufactured by Technovision, Inc.). Next, a dicing device (product name: DFD-6340, manufactured by DISCO CORPORATION) equipped with two-axis dicing blades (Z1: NBC-ZH2050 (27HEDD), manufactured by DISCO CORPORATION/Z2: NBC-ZH127F-SE (BC), manufactured by DISCO CORPORATION) was used to perform dicing from the dummy silicon wafer side to a size of 2 mm×2 mm (thickness of the adhesive layer: 1.0 μm), which is then heat treated at 180° C. for one hour to obtain a dummy chip with the cured film-like adhesive.

Using the film-like adhesive with release film obtained in each Working Example and Comparative Example in the similar processing method, dicing was performed from the dummy silicon wafer side to a size of 12 mm×12 mm, which is then heat treated at 180° C. for one hour to obtain a dummy chip with the cured film-like adhesive (the thickness of the adhesive: 1.0 μm).

Next, using a flip chip bonder (product name: TFC Z100C, manufactured by Shibaura Mechatronics Corporation), the 2 mm×2 mm dummy chip with the cured film-like adhesive 12 (see FIG. 4, however, the dummy chip is narrower than the one shown) was picked up from the dicing tape and mounted on the 12 mm×12 mm dummy chip with the cured film-like adhesive 13 installed on a stage so that the film-like adhesives were bonded to each other. The mounting conditions at this time were as follows. Note that when the temperature of a collet 11 was raised to 200° C., the temperature of the stage 14 was also raised to 150° C.
Collet 11 temperature: room temperature (25° C.) or 200° C.;
Stage 14 temperature: room temperature (25° C.) or 150° C.;
Bonding pressure: 10 N;
Bonding time: 10 seconds.

The die-shear strength of the bonded dummy chips with the film-like adhesives at room temperature (25° C.) was measured using a bond tester (product name: Universal Bond Tester 4000, manufactured by Dage Group). Specifically, as shown in FIG. 6, for the 2 mm×2 mm dummy chip 12 adhered to the 12 mm×12 mm dummy chip 13, the 2 mm×2 mm dummy chip 12 was pushed from a side to apply a load at a height of 10 μm from a surface of an adherend using a specified shearing jig 15 at a shear speed of 0.5 mm/see, and the strength at breakage was measured at room temperature (25° C.). The average value of the 8 tests was calculated as the die-shear strength. Die-shear strength evaluation was performed based on the following evaluation criteria. In this test, an evaluation rank of “A” is a passing level (in accordance with MIL-STD-883 method number 2019). Note that the die-shear strength corresponds to the bonding strength according to the present invention.
AAA: Die-shear strength average value is 40 MPa or more;
AA: Die-shear strength average value is less than 40 MPa and 20 MPa or more;
A: Die-shear strength average value is less than 20 MPa and 10 MPa or more;
B: Die-shear strength average value is less than 10 MPa and 5 MPa or more;
C: Die-shear strength average value is less than 5 MPa.

### Working Example 1

Firstly, 60 parts by mass of bisphenol A type epoxy resin (product name: YD-012, weight average molecular weight: 1,000, softening point: 81° C., solid, epoxy equivalent: 655, manufactured by NIPPON STEEL Chemical & Material Co., Ltd.), 140 parts by mass of flexible epoxy resin (product name: YX-7105, weight average molecular weight: 600, softening point: 25° C. or less, liquid, epoxy equivalent: 487, manufactured by Mitsubishi Chemical Corporation), 100 parts by mass of bisphenol A type phenoxy resin (product name: YP-50, mass average molecular weight: 70,000, Tg: 84° C., manufactured by NSCC Epoxy Manufacturing Co., Ltd.), and 67 parts by mass of MEK were heated and stirred at a temperature of 110° C. for 2 hours in a 1,000 ml separable flask to obtain resin varnish.

Next, 367 parts by mass of the resin varnish was transferred to an 800 ml planetary mixer, 240 parts by mass of silica filler (product name: SO-C1, average particle size (d50): 0.3 μm, manufactured by ADMATECHS CO., LTD.) was added, and 2.5 parts by mass of an imidazole type curing agent (product name: 2PHZ-PW, manufactured by SHIKOKU KASEI HOLDINGS CORPORATION) and 3.0 parts by mass of a silane coupling agent (product name: S-510, manufactured by JNC Corporation) were added, and after stirring and mixing at room temperature for 1 hour, vacuum defoaming was performed to obtain mixed varnish (an adhesive composition).

Next, the obtained mixed varnish was applied to a 38 μm thick release-treated PET film (a release film) using a multi-coater (head part: knife coater, model: MPC-400L, manufactured by Matsuoka Machine Works, Co., Ltd.) at a processing temperature of 130° C. (drying oven 1.5 m) and a linear speed of 1.0 m/min (residence time 1.5 min) to produce a double-layered film (a film-like adhesive with a release film) in which an adhesive layer having a width of 200 mm, a length of 10 m and a thickness of 1 μm is formed on the release film. The bonding temperature (collet temperature) for the evaluation on bonding properties and die-shear was set to 200° C. The sampling temperature for the viscoelastic properties was also set at the above bonding temperature (200° C.).

### Working Example 2

An adhesive composition and a film-like adhesive were obtained in the same manner as in Working Example 1 except that 30 parts by mass of bisphenol A type epoxy resin (product name: YD-012, weight average molecular weight: 1,000, softening point: 81° C., solid, epoxy equivalent: 655, NIPPON STEEL Chemical & Material Co., Ltd.) and 170 parts by mass of flexible epoxy resin (product name: YX-7105, weight average molecular weight: 600, softening point: 25° C. or less, liquid, epoxy equivalent: 487, manufactured by Mitsubishi Chemical Corporation) were used. The bonding temperature (collet temperature) for the evaluation on bonding properties and die-shear was set to 200° C. The sampling temperature for the viscoelastic properties was also set at the above bonding temperature (200° C.).

### Working Example 3

An adhesive composition and a film-like adhesive were obtained in the same manner as in Working Example 1 except that 0 parts by mass of bisphenol A type epoxy resin (product name: YD-012, weight average molecular weight: 1,000, softening point: 81° C., solid, epoxy equivalent: 655, NIPPON STEEL Chemical & Material Co., Ltd.) and 200 parts by mass of flexible epoxy resin (product name: YX-7105, weight average molecular weight: 600, softening point: 25° C. or less, liquid, epoxy equivalent: 487, manufactured by Mitsubishi Chemical Corporation) were used. The bonding temperature (collet temperature) for the evaluation on bonding properties and die-shear was set to 200° C. The sampling temperature for the viscoelastic properties was also set at the above bonding temperature (200° C.).

### Working Example 4

An adhesive composition and a film-like adhesive were obtained in the same manner as in Working Example 1 except that, instead of phenoxy resin, 400 parts by mass of urethane resin solution (product name: Dynaleo VA-9310MF, weight average molecular weight: 110,000, Tg: 27° C., room temperature elastic modulus: 289 MPa, solvent: MEK/IPA mixed solvent, manufactured by TOYOCHEM CO., LTD.) (including 100 parts by mass of urethane resin) was used. The bonding temperature (collet temperature) for the evaluation on bonding properties and die-shear was set to 200° C. The sampling temperature for the viscoelastic properties was also set at the above bonding temperature (200° C.).

### Working Example 5

An adhesive composition and a film-like adhesive were obtained in the same manner as in Working Example 4 except that the collet temperature for the evaluation on bonding properties and die-shear as well as the sampling temperature for the viscoelastic properties were set to 25° C.

### Working Example 6

An adhesive composition and a film-like adhesive were obtained in the same manner as in Working Example 1 except that, in place of YX-7105, 140 parts by mass of flexible epoxy resin (product name: AER9000, weight average molecular weight: 500, softening point: 25° C. or less, liquid, epoxy equivalent: 375, manufactured by Asahi Kasei Corporation) was used. The bonding temperature (collet temperature) for the evaluation on bonding properties and die-shear was set to 200° C. The sampling temperature for the viscoelastic properties was also set at the above bonding temperature (200° C.).

### Working Example 7

An adhesive composition and a film-like adhesive were obtained in the same manner as in Working Example 6 except that the collet temperature for the evaluation on bonding properties and die-shear as well as the sampling temperature for the viscoelastic properties were set to 25° C.

### Working Example 8

An adhesive composition and a film-like adhesive were obtained in the same manner as in Working Example 1 except that, instead of phenoxy resin, 400 parts by mass of an acrylic polymer solution (product name: S-2060, mass average molecular weight: 500,000, Tg: −23° C., room temperature (25° C.) elastic modulus: 50 MPa, solid content 25% (organic solvent: toluene), manufactured by TOAGOSEI CO., LTD.) (including 100 parts by mass of an acrylic polymer) was used. The bonding temperature (collet temperature) for the evaluation on bonding properties and die-shear was set to 200° C. The sampling temperature for the viscoelastic properties was also set at the above bonding temperature (200° C.).

### Working Example 9

An adhesive composition and a film-like adhesive were obtained in the same manner as in Working Example 5 except that the silica filler (product name: SO-C1, average particle size (d50): 0.3 μm, manufactured by ADMATECHS CO., LTD.) and the silane coupling agent (product name: S-510, manufactured by JNC Corporation) were not used. The collet temperature for the evaluation on bonding properties and die-shear as well as the sampling temperature for the viscoelastic properties were set to 25° C.

### Working Example 10

An adhesive composition and a film-like adhesive were obtained in the same manner as in Working Example 9 except that, in place of YX-7105, 140 parts by mass of flexible epoxy resin (product name: AER9000, weight average molecular weight: 500, softening point: 25° C. or less, liquid, epoxy equivalent: 375, manufactured by Asahi Kasei Corporation) was used. The collet temperature for the evaluation on bonding properties and die-shear as well as the sampling temperature for the viscoelastic properties were set to 25° C.

### Comparative Example 1

An adhesive composition and a film-like adhesive were obtained in the same manner as in Working Example 1 except that, in place of YX-7105, 140 parts by mass of bisphenol A type epoxy resin (product name: YD-128, weight average molecular weight: 400, softening point: 25° C. or less, liquid, epoxy equivalent: 190, manufactured by NSCC Epoxy Manufacturing Co., Ltd.) and 840 parts by mass of a silica filler (product name: SO-C1, average particle size (d50): 0.3 μm, manufactured by ADMATECHS CO., LTD.) were used. The bonding temperature (collet temperature) for the evaluation on bonding properties and die-shear was set to 200° C. The sampling temperature for the viscoelastic properties was also set at the above bonding temperature (200° C.).

### Comparative Example 2

An adhesive composition and a film-like adhesive were obtained in the same manner as in Comparative Example 1 except that 240 parts by mass of a silica filler (product name: SO-C1, average particle size (d50): 0.3 μm, manufactured by ADMATECHS CO., LTD.) was used. The bonding temperature (collet temperature) for the evaluation on bonding properties and die-shear was set to 200° C. The sampling temperature for the viscoelastic properties was also set at the above bonding temperature (200° C.).

### Comparative Example 3

An adhesive composition and a film-like adhesive were obtained in the same manner as in Comparative Example 1 except that the silica filler (product name: SO-C1, average particle size (d50): 0.3 μm, manufactured by ADMATECHS CO., LTD.) was not used. The bonding temperature (collet temperature) for the evaluation on bonding properties and die-shear was set to 200° C. The sampling temperature for the viscoelastic properties was also set at the above bonding temperature (200° C.).

### Comparative Example 4

An adhesive composition and a film-like adhesive were obtained in the same manner as in Working Example 1 except that 150 parts by mass of bisphenol A type epoxy resin (product name: YD-012, weight average molecular weight: 1000, softening point: 81° C., solid, epoxy equivalent: 655, manufactured by NIPPON STEEL Chemical & Material Co., Ltd.) and 50 parts by mass of flexible epoxy resin (product name: YX-7105, weight average molecular weight: 600, softening point: 25° C. or less, liquid, epoxy equivalent: 487, manufactured by Mitsubishi Chemical Corporation) were used. The collet temperature for the evaluation on bonding properties and die-shear as well as the sampling temperature for the viscoelastic properties were set to 25° C.

TABLE 2

| | | | | Working Examples | | | | | | | | | |
|---|---|---|---|---|---|---|---|---|---|---|---|---|---|
| | | | Epoxy | Work- | Work- | Work- | Work- | Work- | Work- | Work- | Work- | Work- | Work- |
| | | | Equiv- | ing | ing | ing | ing | ing | ing | ing | ing | ing | ing |
| | | | alent | Exam- | Exam- | Exam- | Exam- | Exam- | Exam- | Exam- | Exam- | Exam- | Exam- |
| Standard | | | (g/eq) | ple 1 | ple 2 | ple 3 | ple 4 | ple 5 | ple 6 | ple 7 | ple 8 | ple 9 | ple 10 |
| Film- | Epoxy | YD-012 | 655 | 60 | 30 | | 60 | 60 | 60 | 60 | 60 | 60 | 60 |
| like | Resin | (Solid | | | | | | | | | | | |
| Adhesive | (A) | BisA-type | | | | | | | | | | | |
| Compo- | | Epoxy | | | | | | | | | | | |
| sition | | Resin) | | | | | | | | | | | |
| [parts | | YX-7105 | 487 | 140 | 170 | 200 | 140 | 140 | | | 140 | 140 | |
| by mass] | | (Liquid | | | | | | | | | | | |
| | | Flexible | | | | | | | | | | | |
| | | Epoxy | | | | | | | | | | | |
| | | Resin) | | | | | | | | | | | |
| | | AER9000 | 375 | | | | | | 140 | 140 | | | 140 |
| | | (Liquid | | | | | | | | | | | |
| | | Flexible | | | | | | | | | | | |
| | | Epoxy | | | | | | | | | | | |
| | | Resin) | | | | | | | | | | | |

| | | | | | | | | | | | |
|---|---|---|---|---|---|---|---|---|---|---|---|
| Polymer | YP-50 (BisA- | 100 | 100 | 100 | | | 100 | 100 | | | |
| Component | type phenoxy | | | | | | | | | | |
| (C) | resin) 70,000*¹ | | | | | | | | | | |
| | VA-9310MF | | | | 100 | 100 | | | | 100 | 100 |
| | (Urethane | | | | | | | | | | |
| | Resin) 110,000*¹ | | | | | | | | | | |
| | S-2060 | | | | | | | | 100 | | |
| | (Acrylic | | | | | | | | | | |
| | Resin) 500,000*¹ | | | | | | | | | | |
| Filler | SO-C1 (Average | 240 | 240 | 240 | 240 | 240 | 240 | 240 | 240 | | |
| | Particle Size 0.3 μm | | | | | | | | | | |
| | Silica Filler) | | | | | | | | | | |

| | | | | | | | | | | |
|---|---|---|---|---|---|---|---|---|---|---|
| Silane Coupling Agent | 3 | 3 | 3 | 3 | 3 | 3 | 3 | 3 | | |
| S-510 (Epoxy Silane- | | | | | | | | | | |
| type Silane | | | | | | | | | | |
| Coupling Agent) | | | | | | | | | | |
| Epoxy Resin | 2.5 | 2.5 | 2.5 | 2.5 | 2.5 | 2.5 | 2.5 | 2.5 | 2.5 | 2.5 |
| Curing Agent (B) | | | | | | | | | | |
| 2PHZ-PW (Imidazole- | | | | | | | | | | |
| based Curing Agent) | | | | | | | | | | |
| Total Solids | 546 | 546 | 546 | 546 | 546 | 546 | 546 | 546 | 163 | 303 |
| Filler filling | 30.0% | 30.0% | 30.0% | 30.0% | 30.0% | 30.0% | 30.0% | 30.0% | 0.0% | 0.0% |
| amount (vol %) | | | | | | | | | | |
| Content Rate of Stress-Relieving | 46.7% | 56.7% | 66.7% | 46.7% | 46.7% | 46.7% | 46.7% | 46.7% | 46.7% | 46.7% |
| Epoxy Resin (Liquid Flexible | | | | | | | | | | |
| Epoxy Resin) to Total Resin | | | | | | | | | | |
| of Epoxy Resin (A) + | | | | | | | | | | |
| Polymer Component (C) | | | | | | | | | | |

| | | | | | | | | | | |
|---|---|---|---|---|---|---|---|---|---|---|
| Bonding (Collet) Temperature for | 200° C. | 200° C. | 200° C. | 200° C. | 25° C. | 200° C. | 25° C. | 200° C. | 25° C. | 25° C. |
| Evaluations on Bonding Properties | | | | | | | | | | |
| and Die-shear | | | | | | | | | | |
| Storage Elastic Modulus E′/MPa | 23.4 | 13.1 | 10.0 | 8.4 | 1422 | 6.4 | 1585 | 80 | 3.5 | 2.1 |
| at Bonding Temperature | | | | | | | | | | |
| Loss Elastic Modulus E″/Pa | 1.0 | 0.8 | 0.7 | 0.22 | 280 | 0.22 | 418 | 3 | 0.11 | 0.09 |
| at Bonding Temperature | | | | | | | | | | |
| Loss Tangent tan δ at | 0.04 | 0.06 | 0.07 | 0.03 | 0.20 | 0.03 | 0.26 | 0.04 | 0.03 | 0.04 |
| Bonding Temperature | | | | | | | | | | |
| Evaluation on | AA | AA | AA | AA | A | AA | A | A | AA | AA |
| Bonding Properties | | | | | | | | | | |
| Die-Shear Strength | AA | AAA | AAA | AAA | AA | AAA | A | A | AAA | AAA |
| (Bonding Strength) | | | | | | | | | | |

*¹Weight Average Molecular Weight

TABLE 3

| | | | | Comparative Examples | | | |
|---|---|---|---|---|---|---|---|
| | | | | Compar- | Compar- | Compar- | Compar- |
| | | | Epoxy | ative | ative | ative | ative |
| | | | Equivalent | Exam- | Exam- | Exam- | Exam- |
| Standard | | | (g/eq) | ple 1 | ple 2 | ple 3 | Eple 4 |
| Film- | Epoxy | YD-012 | 655 | 60 | 60 | 60 | 150 |
| like | Resin | (Solid | | | | | |
| Adhesive | (A) | BisA-type | | | | | |
| Composition | | Epoxy | | | | | |
| | | Resin) | | | | | |
| | | YX-7105 | 480 | | | | 50 |
| | | (Liquid | | | | | |
| | | Flexible | | | | | |
| | | Epoxy | | | | | |
| | | Resin)) | | | | | |
| | | YD-128 | 189 | 140 | 140 | 140 | |
| | | (Liquid | | | | | |
| | | BisA-type | | | | | |
| | | Epoxy | | | | | |
| | | Resin) | | | | | |

| | | | | | |
|---|---|---|---|---|---|
| Polymer | YP-50 (BisA- | 100 | 100 | 100 | 100 |
| Component | type phenoxy | | | | |
| (C) | resin) 70,000*¹ | | | | |
| Filler | SO-C1 (Average | 840 | 240 | | 240 |
| | Particle Size 0.3 μm | | | | |
| | Silica Filler) | | | | |

| | | | | |
|---|---|---|---|---|
| Silane Coupling Agent | 3 | 3 | | 3 |
| S-510 (Epoxy Silane- | | | | |
| type Silane | | | | |
| Coupling Agent) | | | | |
| Epoxy Resin | 2.5 | 2.5 | 2.5 | 2.5 |
| Curing Agent (B) | | | | |
| 2PHZ-PW (Imidazole- | | | | |
| based Curing Agent) | | | | |
| Total Solids | 1146 | 546 | 303 | 546 |
| Filler filling | 60.0% | 30.0% | 0.0% | 30.0% |
| amount (vol %) | | | | |
| Content Rate of Stress-Relieving | 0.0% | 0.0% | 0.0% | 16.7% |
| Epoxy Resin (Liquid Flexible | | | | |
| Epoxy Resin) to Total Resin | | | | |
| of Epoxy Resin (A) + | | | | |
| Polymer Component (C) | | | | |

| | | | | |
|---|---|---|---|---|
| Bonding (Collet) Temperature for | 200° C. | 200° C. | 200° C. | 25° C. |
| Evaluations on Bonding Properties | | | | |
| and Die-shear | | | | |
| Storage Elastic Modulus E′/MPa | 2400 | 1650 | 900 | 2200 |
| at Bonding Temperature | | | | |
| Loss Elastic Modulus E″/Pa | 800 | 40 | 20 | 550 |
| at Bonding Temperature | | | | |
| Loss Tangent tan δ at | 0.33 | 0.02 | 0.02 | 0.25 |
| Bonding Temperature | | | | |
| Evaluation on | B | B | B | B |
| Bonding Properties | | | | |
| Die-Shear Strength | C | C | B | B |
| (Bonding Strength) | | | | |

*¹Weight Average Molecular Weight

### REVIEW

In any of the adhesive compositions of Working Examples, epoxy resin with an epoxy equivalent of 300 g/eq or more is used, and when made into a film, the adhesive compositions satisfied the properties such as the storage elastic modulus of 2,000 MPa or less and the loss tangent of 0.03 or more at the bonding temperature (25° C., 200° C.). As a result, excellent results were obtained in the evaluations on bonding properties and die-shear strength (A, AA, AAA).

In contrast, in the adhesive compositions of Comparative Examples 1 to 3, the epoxy equivalent of the epoxy resin was 189, which is well below 300, and the storage elastic modulus of 2,000 MPa or less and the loss tangent of 0.03 or more were not satisfied. As a result, insufficient results were obtained in the evaluations on bonding properties and die-shear strength (B, C).

Working Examples 4 and 5, and Working Examples 6 and 7 each have the same composition, in which the values of storage elastic modulus and loss tangent of the present invention were satisfied at the bonding temperature of both 200° C. and 25° C., exhibiting good performance both at the low bonding temperature and when heated.

In the adhesive compositions of Working Examples, a solid epoxy resin and a liquid epoxy resin were blended. Although Working Example 3 is the only example containing the liquid epoxy resin alone, Working Example 3 exhibits good results in the evaluations on both bonding properties and die-shear. However, as mentioned above, if the liquid epoxy resin is used alone, tackiness is too strong and handling becomes poor.

Various polymers such as BisA-type phenoxy resin, urethane resin, and acrylic resin can be used for forming the adhesive composition. However, Working Example 8, in which acrylic resin was used, is rated A in the bonding and die-shear strength evaluations, being inferior to the others. From such the viewpoint, the polymer forming a skeleton of the matrix is preferably phenoxy resin or urethane resin.

Also, in the adhesive compositions of Working Examples, except for Working Example 3, the liquid epoxy resin is richly blended compared to the solid epoxy resin. When this is inverted such that the solid epoxy resin is blended richly as in Comparative Example 4, the results are inferior in the evaluations on bonding properties and die-shear strength.

What is claimed is:

1. An adhesive composition containing at least an epoxy resin (A), an epoxy resin curing agent (B), and a polymer component (C), wherein:
under the following conditions after curing, the adhesive composition has a storage elastic modulus of 2,000 MPa or less and a loss tangent of 0.03 or more, and when the compositions are bonded to one another after curing, bonding strength under the following conditions is 5 MPa or more, the conditions being:
the storage elastic modulus and loss tangent after curing are measured under conditions of a measuring temperature range of 20 to 300° C., a heating rate of 5° C./min, and a frequency of 1 Hz, after thermally curing the adhesive composition at 180° C. for one hour, thereby obtaining a film-like adhesive piece of 5 mm×17 mm×200 μm, and at this time, measured values at a bonding temperature below are sampled;
the bonding temperature is any temperature of 25° C. or more and 300° C. or less; and
the bonding strength is the strength required to peel and separate at room temperature two chips attached with film-like adhesives, each film-like adhesive being made to have a thickness of 1.0 μm by heating the adhesive composition at 180° C. for one hour followed by thermal curing and the two chips being bonded together at the bonding temperature by butting against each other the film-like adhesives of both.

2. The adhesive composition according to claim 1, wherein an epoxy equivalent of the epoxy resin (A) used in the adhesive composition is 300 g/eq or more, and content of the epoxy resin (A) is 20 mass % or more of a total amount of the epoxy resin (A), the epoxy resin curing agent (B), and the polymer component (C).

3. The adhesive composition according to claim 1, wherein the epoxy resin (A) is a blend of an epoxy resin that is liquid at room temperature and an epoxy resin that is solid at room temperature, wherein content of the liquid epoxy resin is 100 to 250 parts by mass and content of the solid epoxy resin is 15 to 90 parts by mass when content of the polymer component (C) is 100 parts by mass, and mass ratio of the solid epoxy resin to the liquid epoxy resin is in a range of 1:10 to 6:10.

4. The adhesive composition according to claim 1, wherein the epoxy resin curing agent (B) is an imidazole-based curing agent.

5. The adhesive composition according to claim 1, wherein the bonding temperature is 25° C. or more and 200° C. or less.

6. A film-like adhesive made by heat treating the adhesive composition according to claim 1.

7. The film-like adhesive according to claim 6, wherein the film-like adhesive has a thickness of 0.1 to 50 μm.

8. A method for manufacturing a semiconductor package comprising:
adhering and thermally curing the film-like adhesive according to claim 6 onto a semiconductor wafer having at least one semiconductor circuit formed on a surface thereof to provide an adhesive layer, and bonding and stacking the semiconductor wafers via the adhesive layers by compressing the adhesive layers at room temperature or through thermal curing to form a resin curing body that can bond the semiconductor wafers to be multi-layered.

9. The method for manufacturing the semiconductor package according to claim 8, the method further comprising:
flattening the adhesive layer such that the terminals are exposed from the adhesive layer and a surface of the adhesive layer and surfaces of the terminals are flush with each other.

10. A semiconductor package comprising:
the semiconductor wafers bonded by the resin curing body of the film-like adhesives according to claim 6.

11. A film-like adhesive made by heat treating an adhesive composition containing at least an epoxy resin (A), an epoxy resin curing agent (B), and a polymer component (C), wherein:
under the following conditions, the film-like adhesive has a storage elastic modulus of 2,000 MPa or less and a loss tangent of 0.03 or more, and bonding strength when bonded under the following conditions is 5 MPa or more, the conditions being:
the storage elastic modulus and loss tangent are measured under conditions of a measuring temperature range of 20 to 300° C., a heating rate of 5° C./min, and a frequency of 1 Hz, thereby obtaining a film-like adhesive piece of 5 mm×17 mm×200 μm, and at this time, measured values at a bonding temperature below are sampled;
the bonding temperature is any temperature of 25° C. or more and 300° C. or less; and
the bonding strength is the strength required to peel and separate at room temperature two chips attached with film-like adhesives, each film-like adhesive being made to have a thickness of 1.0 μm and the two chips being bonded together at the bonding temperature by butting against each other the film-like adhesives of both.
